(19) United States
(12) Patent Application Publication
(10) Pub. No.: US 2009/0181516 A1
(43) Pub. Date: Jul. 16, 2009

(54) Method of Forming Isolation Layer of Semiconductor Device

(76) Inventor: Min Sik Jang, Icheon-Si (KR)

Correspondence Address: MARSHALL, GERSTEIN & BORUN LLP, 233 SOUTH WACKER DRIVE, 6300 SEARS TOWER, CHICAGO, IL, 60606-6357, US

(21) Appl. No.: 12/131,239

(22) Filed: Jun. 2, 2008

(30) Foreign Application Priority Data
Jan. 10, 2008 (KR) 10-2008-003174

(51) Int. Cl. H01L 21/762

(52) U.S. Cl. 438/426; 257/E21.546

(57) ABSTRACT

A method of forming an isolation layer of a semiconductor device is disclosed. In the method according to one aspect, a semiconductor substrate having a trench formed therein is provided. A first insulating layer is formed over an entire surface of the semiconductor substrate including a surface of the trench. A passivation layer, preferably silicon, including oxygen is formed on a surface of the first insulating layer. A second insulating layer is formed on the passivation layer formed within the trench.

### CROSS-REFERENCE TO RELATED APPLICATION

Priority to Korean patent application number 10-2008-003174, filed on Jan. 10, 2008, the disclosure of which is incorporated by reference in its entirety, is claimed.

### BACKGROUND OF THE INVENTION

1. Field of the Disclosure

The present invention relates generally to a method of forming an isolation layer of a semiconductor device and, more particularly, to a method of forming an isolation layer of a semiconductor device, which can prevent damage caused by a curing process in fabrication of an isolation layer.

2. Brief Description of Related Technology

A semiconductor device includes an insulating layer for electrical insulation.

In a semiconductor device, there are many regions that should be electrically insulated, such as an isolation layer, a pre-metal dielectric layer, and spacers. In particular, the isolation layer is formed to electrically insulate neighboring active regions. As semiconductor devices become more highly integrated, the formation process of the isolation layer becomes more difficult. Specifically, to form the isolation layer, a trench is formed in a semiconductor substrate. If the width of the trench is narrowed but the depth remains the same, the aspect ratio of the trench is increased. Thus, in a gap-fill process to gap-fill the trench, problems, such as a void and/or a seam, may occur. This void or seam may cause damage to the inside of the isolation layer in a subsequent etch process and also degrade the electrical properties of the semiconductor device.

Accordingly, to improve the gap-fill characteristic, a flowable SOD (Spin On Dielectric) layer has been used as the insulating layer for the isolation layer. The SOD layer is formed of a flowable material and experiences a curing process for densifying the film quality after the SOD layer is formed. The curing process can be performed using an annealing process. In the curing process, impurities included in the SOD layer are out gassed.

In particular, there may be portions of the SOD layer from which a large amount of impurities is out gassed. Hence, defects where the height of a part of the SOD layer is lowered can be generated. These defects can degrade the electrical properties of the semiconductor device, which may cause a reduction in reliability.

### BRIEF SUMMARY OF THE INVENTION

The present invention is directed to reducing or prohibiting defects, which may occur in an isolation layer at the time of an etch process, by forming a passivation layer including an impurity on a surface of a trench to compensate for the shortage of the impurity caused by a curing process performed after a subsequent flowable insulating layer is formed on the passivation layer.

In accordance with an embodiment, there is provided a method of forming an isolation layer of a semiconductor device. In this method, a semiconductor substrate having a trench formed therein is provided. The substrate preferably has sequentially stacked first and second pad layers on adjacent sides of the trench. A first insulating layer is formed over an entire surface of the semiconductor substrate including a surface of the trench. A passivation layer including oxygen is formed on a surface of the first insulating layer. A second insulating layer is formed on the passivation layer formed within the trench.

A wall insulating layer is optionally formed on the surface of the trench. The wall insulating layer is preferably formed using a wet, dry, radical, plasma or radical auxiliary oxidization process.

The first insulating layer preferably is formed of an oxide layer. The oxide layer preferably is formed by performing a HDP (High Density Plasma) or LPCVD (Low Pressure Chemical Vapor Deposition) method.

The passivation layer preferably is formed of a silicon layer including oxygen, for example, using a furnace or single wafer type. When the furnace is used, the passivation layer preferably is formed in a temperature range of 400 to 700 degrees Celsius and preferably at a pressure in a range of 0.05 to 10 Torr. When the single wafer type is used, the passivation layer preferably is formed in a temperature range of 500 to 800 degrees Celsius and preferably at a pressure in a range of 1 to 500 Torr.

The passivation layer preferably is formed by flowing a silicon source gas, a gas including oxygen, and a carrier gas. Here the gas including oxygen preferably includes N₂O gas or NO gas. The silicon source gas preferably includes SiH₄, DCS (Dichlorosilane), TCS (Triclouro Silane) or TCA (Trichloroethane). The carrier gas preferably includes an inert gas. The inert gas preferably includes N₂ gas or Ar gas.

The second insulating layer preferably is formed of a SOD (Spin On Dielectric) layer. In one embodiment, the passivation layer preferably is oxidized. The oxidization of the passivation layer preferably is performed by a process of densifying the SOD layer.

### BRIEF DESCRIPTION OF THE DRAWINGS

For a more complete understanding of the disclosure, reference should be made to the following detailed description and accompanying drawings.

FIGS. 1A to 1G are sectional views illustrating a method of forming an isolation layer of a semiconductor device.

FIG. 2 is a graph illustrating the concentration of oxygen according to the flow amount of a gas including oxygen.

While the disclosed method is susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DESCRIPTION OF SPECIFIC EMBODIMENTS

An embodiment according to the present invention will be described with reference to the accompanying drawings. However, the present invention is not limited to the disclosed embodiment, but may be implemented in various manners.

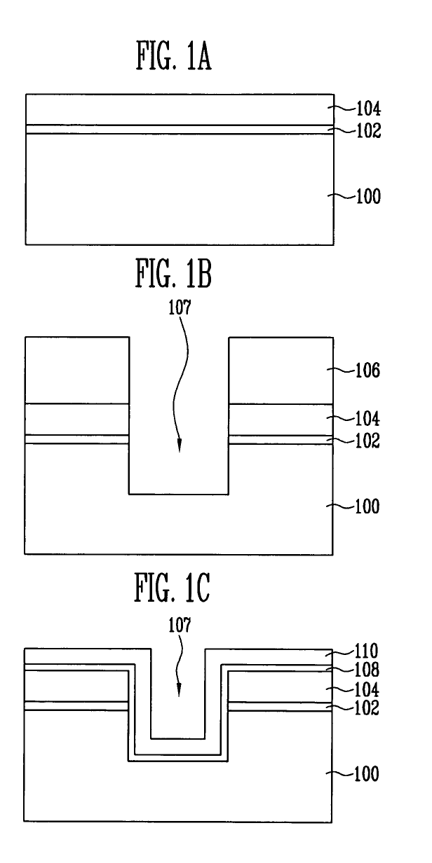

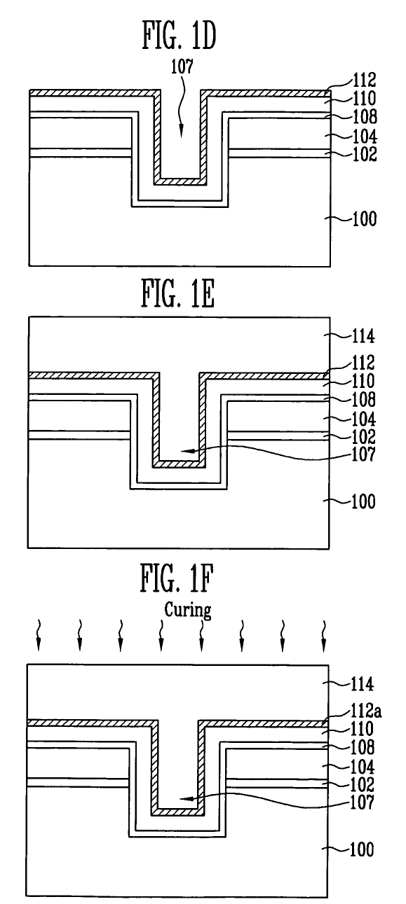

FIGS. 1A to 1G are sectional views illustrating a method of forming an isolation layer of a semiconductor device. Referring to FIG. 1A, a first pad layer 102 and a second pad layer 104 for protecting a surface of a semiconductor substrate 100 are sequentially stacked over the semiconductor substrate 100. The first pad layer 102 can be formed of an oxide layer. The second pad layer 104 can also be used as hard mask layer as well as the pad layer. Thus, the second pad layer 104 can be preferably formed of a nitride layer.

Referring to FIG. 1B, a photoresist pattern 106 having an opened isolation region is formed on the second pad layer 104. A trench 107 is formed by etching, e.g., sequentially, the second pad layer 104, the first pad layer 102 and the semiconductor substrate 100 along the photoresist pattern 106.

Referring to FIG. 1C, after the photoresist pattern (refer to 106 of FIG. 1B) is removed, an optional wall insulating layer 108 is formed to compensate for surface damage within the trench 107, which can be caused by an etch process. The wall insulating layer 108 can be formed using a side wall oxidation process. Specifically, the side wall oxidization process is a process of compensating for etch damage by oxidizing lateral portions and a bottom surface of the trench 107. For example, the side wall oxidization process can be performed using a wet oxidization process, dry oxidization process, radical oxidization process, plasma oxidization process or radical auxiliary oxidization process or combinations thereof.

A first insulating layer 110 for a liner layer is formed on a surface of the trench 107. The first insulating layer 110 can be formed to prevent an impurity from penetrating from a subsequent flowable layer to the semiconductor substrate 100. To this end, the first insulating layer 110 can be preferably formed of an oxide layer. Specifically, the first insulating layer 110 preferably is formed using a HDP (High Density Plasma) or LPCVD (Low Pressure Chemical Vapor Deposition) method.

Referring to FIG. 1D, a passivation layer 112 is formed on a surface of the first insulating layer 110 to prevent the occurrence of defects (for example, depression) due to out-gassing of an impurity (for example, O₂) at the time of a curing process of a subsequent flowable layer. The passivation layer 112 can be preferably formed of a silicon layer including oxygen, for example, using a furnace or single wafer type.

When the furnace is used, the passivation layer 112 is formed by injecting a silicon source gas, a gas including oxygen, and a carrier gas. In particular, the passivation layer 112 preferably is formed at a temperature lower than that where oxidization is generated, for example, within a range of 400 to 600 degrees Celsius. Hence, the passivation layer 112 includes oxygen without being oxidized. Further, the passivation layer 112 preferably is formed at a pressure in a range of 0.05 to 10 Torr. Here, the silicon source gas preferably includes SiH₄, DCS (Dichlorosilane), TCS (Triclouro Silane) or TCA (Trichloroethane). The gas including oxygen preferably includes N₂O or NO gas. The carrier gas preferably includes an inert gas (for example, N₂ or Ar gas).

When the single wafer type is used, the passivation layer 112 can be formed by injecting a silicon source gas, a gas including oxygen, and a carrier gas at a temperature lower than that where oxidization is generated, for example, within a range of 500 to 700 degrees Celsius. Further, the passivation layer 112 preferably is formed at a pressure in a range of 1 to 500 Torr. The silicon source gas preferably includes SiH₄, DCS, TCS or TCA. The gas including oxygen preferably includes N₂O or NO gas. The carrier gas preferably includes an inert gas (for example, N₂ or Ar gas).

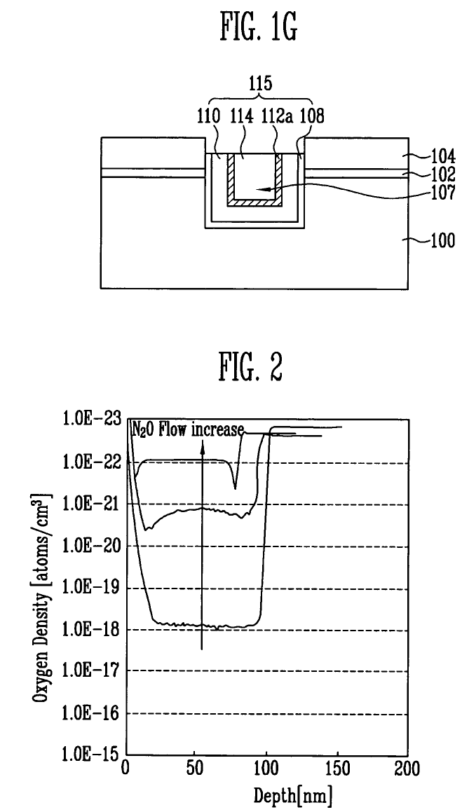

FIG. 2 is a graph illustrating the concentration of oxygen formed in the passivation layer 112 according to the flow amount of a gas including oxygen (for example, N₂O gas) using the furnace. From FIG. 2, it can be seen that when forming the passivation layer 112, the greater the flow amount of the gas including oxygen, the higher the concentration of oxygen included in the passivation layer 112.

If the passivation layer 112 is formed of a silicon layer into which oxygen is not injected, an oxidization amount at the time of the curing process may be short. Further, the passivation layer would have to be formed thinly (for example, in a range of 10 to 50 angstrom) to reduce the residue of the silicon layer, which may make the process difficult. However, if a gas including oxygen (for example, N₂O gas or NO gas) is supplied simultaneously when forming the passivation layer 112 as in the present invention, the concentration of the oxygen can be increased, which can supplement oxygen. Furthermore, because a passivation layer 112 of silicon is likely to be oxidized, the passivation layer 112 can be formed thickly (for example, in a range of 50 to 100 angstrom).

Referring to FIG. 1E, a second insulating layer 114 for an isolation layer is formed on the passivation layer 112 to gap-fill the inside of the trench 107. The second insulating layer 114 can be formed of an oxide layer, preferably a SOD layer. The SOD layer is a flowable material and, therefore, can easily gap-fill the trench 107 even though the width of the trench 107 is narrowed due to a higher degree of integration of a semiconductor device. The SOD layer can be formed of, for example, a PSZ (perhydro-polysilane) layer.

Referring to FIG. 1F, after the flowable second insulating layer 114 is formed, a curing process is carried out to densify the film quality. The curing process can be a thermal treatment process. When the second insulating layer 114 is formed of the PSZ layer, thermal treatment can be performed under H₂O or O₂ ambient. At the time of the thermal treatment process, impurities (for example, N₂, NH₃ or NO) are generated and out-gassed. In particular, during the curing process, the passivation layer (refer to 112 of FIG. 1E) is oxidized and thus changes to an oxidized passivation layer 112a. The impurities, which have been out-gassed from the second insulating layer 114, can be supplemented in the oxidized passivation layer 112a, so densification can be improved uniformly.

Referring to FIG. 1G, a polishing process is performed to expose the second pad layer 104. Specifically, the polishing process can be performed on the second insulating layer 114 using, for example, a CMP (Chemical Mechanical Polishing) process so that the second pad layer 104 is exposed. An isolation layer 115 is thereby formed.

An etch process (for example, a wet etch process) preferably is then performed to control the height of the isolation layer 115. Because the densification of the isolation layer 115 has been improved uniformly, defects (for example, depression) formed during the polishing process or the process of controlling the height of the isolation layer can be prevented. Accordingly, because the isolation layer 115 can be controlled to have a uniform height, degradation of the electrical properties of the semiconductor device can be reduced or prevented.

As described above, according to the present invention, the passivation layer including impurities is formed on a surface of the trench to compensate for the shortage of the impurities at the time of a curing process performed after a subsequent flowable insulating layer is formed. Accordingly, defects can be prevented from occurring in the isolation layer due to an etch process. Further, since degradation of the electrical properties of a semiconductor device is reduced or prohibited, reliability of the device can be improved.

The embodiment disclosed herein has been proposed to allow a person skilled in the art to easily implement the present invention, and the person skilled in the part may implement the present invention by a combination of various embodiments. Therefore, the scope of the present invention is not limited by or to the embodiment as described above, and should be construed to be defined only by the appended claims and their equivalents.

What is claimed is:

1. A method of forming an isolation layer of a semiconductor device comprising:
providing a semiconductor substrate having a trench formed therein;
forming a first insulating layer over an entire surface of the semiconductor substrate including a surface of the trench;
forming a passivation layer including oxygen on a surface of the first insulating layer; and
forming a second insulating layer on the passivation layer formed within the trench.

2. The method of claim 1, further comprising forming a wall insulating layer on the surface of the trench before forming the first insulating layer.

3. The method of claim 1, comprising forming the first insulating layer of an oxide layer.

4. The method of claim 3 comprising forming the oxide layer by performing a High Density Plasma or a Low Pressure Chemical Vapor Deposition method.

5. The method of claim 1, comprising forming the passivation layer using a furnace or single wafer type.

6. The method of claim 5, comprising forming the passivation layer using a furnace at a temperature range of 400 to 700 degrees Celsius and at a pressure in a range of 0.05 to 10 Torr.

7. The method of claim 5, comprising forming the passivation layer using a single wafer type at a temperature range of 500 to 800 degrees Celsius and at a pressure in a range of 1 to 500 Torr.

8. The method of claim 1, comprising forming the passivation layer by flowing a silicon source gas, a gas including oxygen, and a carrier gas.

9. The method of claim 8, wherein the gas including oxygen comprises one or both of N₂O gas and NO gas.

10. The method of claim 8, wherein the silicon source gas comprises one or more of SiH₄, Dichlorosilane, Trichlorosilane and Trichloroethane.

11. The method of claim 8, wherein the carrier gas comprises an inert gas.

12. The method of claim 11, wherein the inert gas comprises one or both of N₂ gas and Ar gas.

13. The method of claim 1, comprising forming the second insulating layer of a Spin On Dielectric layer.

14. The method of claim 1, wherein first and second pad layers are stacked over the semiconductor substrate on adjacent sides of the trench.

15. The method of claim 1 further comprising oxidizing the passivation layer.

16. The method of claim 2, comprising forming the wall insulating layer by performing an oxidization process.

17. The method of claim 16, wherein the oxidization process is a wet oxidization process, a dry oxidization process, a radical oxidization process, a plasma oxidization process or a radical auxiliary oxidization process.

18. The method of claim 1, comprising forming the passivation layer of a silicon layer including oxygen.

19. The method of claim 18, comprising forming the passivation layer by injecting a mixed gas including one or both of N₂O gas and NO gas.

20. A method of forming an isolation layer of a semiconductor device comprising:
providing a semiconductor substrate having a trench formed therein;
forming a wall insulating layer on the surface of the trench;
forming a first insulating layer over a surface of the wall insulating layer;
forming a silicon layer including oxygen on a surface of the first insulating layer;
forming a second insulating layer on the passivation layer formed within the trench.

21. The method of claim 20, comprising oxidizing the passivation layer by densifying the second insulating layer.
